(19) United States
(12) Patent Application Publication
(10) Pub. No.: US 2024/0319580 A1
(43) Pub. Date: Sep. 26, 2024

(54) PROCESS PROXIMITY CORRECTION METHOD BASED ON MACHINE LEARNING, OPTICAL PROXIMITY CORRECTION METHOD INCLUDING THE SAME, AND METHOD OF MANUFACTURING MASK BY USING THE PROCESS PROXIMITY CORRECTION METHOD

(71) Applicant: SAMSUNG ELECTRONICS CO., LTD., Suwon-si (KR)

(72) Inventors: Jaeyong Jeong, Suwon-si (KR); Bonhyun Gu, Suwon-si (KR); Sooyong Lee, Suwon-si (KR)

(21) Appl. No.: 18/529,781

(22) Filed: Dec. 5, 2023

(30) Foreign Application Priority Data
Mar. 24, 2023 (KR) 10-2023-0039255
Mar. 29, 2023 (KR) 10-2023-0041500

(51) Int. Cl. G03F 1/36; G03F 1/84

(52) U.S. Cl. CPC G03F 1/36; G03F 1/84

(57) ABSTRACT

The present disclosure relates to process proximity correction (PPC) methods based on machine learning (ML), optical proximity correction (OPC) methods, and mask manufacturing methods including the PPC methods. One example PPC method based on ML includes obtaining a pattern gauge-based bottom critical dimension (CD) and obtaining pattern gauge-based features from a first layout, performing a gauge clustering operation of grouping and classifying pattern gauges including similar features, calculating distribution parameters in a skew-normal distribution of the pattern gauge-based bottom CD in each cluster, performing ML between the distribution parameters and a feature in each cluster to generate a prediction ML model, predicting a distribution, a maximum limit, and a minimum limit of the pattern gauge-based bottom CD by using the prediction ML model, generating an after cleaning inspection (ACI) target including a maximum process window, and generating a second layout by performing an development inspection (ADI) retarget operation.

### CROSS-REFERENCE TO RELATED APPLICATIONS

This application claims benefit of priority to Korean Patent Application Nos. 10-2023-0039255, filed on Mar. 24, 2023, and 10-2023-0041500, filed on Mar. 29, 2023, in the Korean Intellectual Property Office, the disclosures of which are incorporated by reference herein in their entireties.

### BACKGROUND

The present disclosure relates to a method of manufacturing a mask, and more particularly, to a process proximity correction (PPC) method, an optical proximity correction (OPC) method including the same, and a method of manufacturing a mask by using the PPC method.

In a semiconductor process, a photolithography process using a mask may be performed for forming a pattern on a semiconductor substrate such as a wafer. A mask may be referred to as a pattern transfer artifact where a pattern shape of an opaque material is formed on a transparent substrate material. To manufacture such a mask, a layout of a desired pattern is first designed, and then, OPC-performed layout data obtained through OPC is transferred as mask tape-out (MTO) design data. Subsequently, mask data preparation (MDP) may be performed based on the MTO design data and an exposure process may be performed on a mask substrate.

### SUMMARY

The present disclosure relates to a PPC method based on machine learning (ML), an OPC method including the PPC method, and a method of manufacturing a mask by using the PPC method, which may maximize a process window.

The object of the present disclosure is not limited to the aforesaid, but other objects not described herein will be clearly understood by those of ordinary skill in the art from descriptions below.

In some aspects, a PPC method based on ML includes obtaining a pattern gauge-based critical dimension (CD) through measurement of patterns on a wafer and obtaining pattern gauge-based features from a first layout corresponding to the patterns on the wafer, performing a gauge clustering operation of grouping and classifying pattern gauges including similar features, calculating distribution parameters in a skew-normal distribution of the pattern gauge-based bottom CD in each cluster, performing ML between the distribution parameters and a feature in each cluster to generate a prediction ML model, predicting a distribution, a maximum limit, and a minimum limit of the pattern gauge-based bottom CD based on a feature by using the prediction ML model, generating an after cleaning inspection (ACI) target including a maximum process window with respect to the maximum limit and the minimum limit of the pattern-based bottom CD, and generating a second layout by performing an after development inspection (ADI) retarget operation to correspond to the ACI target.

In other aspects, an OPC method includes obtaining a first layout of ACI corresponding to patterns on a wafer, performing PPC based on ML to generate a second layout of ADI, performing OPC on the second layout to generate a third layout, wherein the performing of the PPC based on ML includes obtaining a pattern gauge-based CD and features, generating a prediction ML model, based on the pattern gauge-based CD and features, and generating an ACI target including a maximum process window with respect to a maximum limit and a minimum limit of the pattern gauge-based bottom CD predicted through the prediction ML model.

In other aspects, a method of manufacturing a mask includes obtaining a first layout of ACI corresponding to patterns on a wafer, performing PPC based on ML to generate a second layout of ADI, performing OPC on the second layout to generate a third layout, transferring the third layout as MTO design data, preparing mask data based on the MTO design data, and exposing a mask substrate, based on the mask data, wherein the performing of the PPC based on ML includes obtaining a pattern gauge-based CD and features, generating a prediction ML model, based on the pattern gauge-based CD and features, and generating an ACI target including a maximum process window with respect to a maximum limit and a minimum limit of the pattern gauge-based bottom CD predicted through the prediction ML model.

### BRIEF DESCRIPTION OF THE DRAWINGS

The above and other aspects, features, and advantages of the present disclosure will be more clearly understood from the following detailed description, taken in conjunction with the accompanying drawings.

FIG. 1 is a flowchart schematically illustrating an example process of an OPC method including a PPC method based on ML.

FIGS. 2A to 2C are an example cross-sectional view of a high aspect ratio contract (HARC) layer of an extension region of a VNAND flash memory, an example plan view of an ADI target of the HARC layer, and an example scanning electron microscope (SEM) photograph of an ACI bottom critical dimension of the HARC layer.

FIG. 3 is a flowchart illustrating in more detail an example operation of performing PPC based on ML, in the OPC method of FIG. 1.

FIG. 4 is a graph of feature-based weights for describing an example operation of calculating feature-based weights, in the PPC method based on ML of FIG. 3.

FIG. 5 is a gauge distribution graph of features for describing an example operation of performing gauge clustering in the PPC method based on ML of FIG. 3.

FIGS. 6A and 6B are graphs of bottom CDs for describing an example operation of removing an outlier and an example operation of calculating distribution parameters, in the PPC method based on ML of FIG. 3.

FIGS. 7A to 7D are example graphs showing prediction values of distribution parameters based on a prediction ML model and real values of distribution parameters, in the PPC method based on ML of FIG. 3.

FIG. 8 is a graph for describing an example operation of predicting a bottom CD distribution and maximum and minimum limits and an example operation of generating an ACI target, in the PPC method based on ML of FIG. 3.

FIG. 9 is a flowchart schematically illustrating a process of an example method of manufacturing a mask by using a PPC method based on ML.

### DETAILED DESCRIPTION

Hereinafter, example implementations will be described in detail with reference to the accompanying drawings. Like reference numerals refer to like elements in the drawings, and their repeated descriptions are omitted.

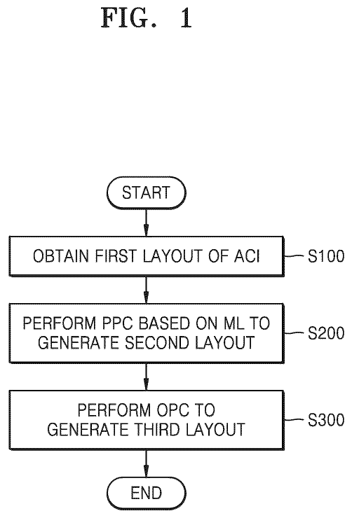

FIG. 1 is a flowchart schematically illustrating an example process of an OPC method including a PPC method based on ML.

Referring to FIG. 1, in the OPC method including the PPC method based on ML in some implementations, a first layout of ACI corresponding to patterns on a wafer may be first obtained in operation S100. In other words, the first layout may be a target layout which is to be obtained in ACI. Here, the ACI may denote inspection of patterns formed on a wafer after an etching process and a cleaning process. The operation S100 of obtaining the first layout of the ACI may include a process of connecting measured data of the ACI with the first layout. For example, the measured data of the ACI may be converted into data such as a polygon, coordinates, and a vertex of the first layout.

Subsequently, to generate a second layout, PPC based on ML may be performed in operation S200. The PPC may denote a method of predicting an ACI CD and correcting a layout in an etching process after a photo process. That is, the PPC may denote an operation of compensating for deformation of shapes of patterns caused by an influence of etching skew and influences of features of the patterns when performing etching. For example, the PPC may denote an operation which previously deforms the shape of a portion which is predicted to be deformed through etching performed on a certain pattern, reflects a deformed shape of the portion in a layout, and previously compensates for deformation of the shape of the pattern in performing etching.

In the OPC method in some implementations, the PPC based ML may obtain pattern gauge-based bottom CDs of patterns on a wafer, obtain features of patterns from the first layout, and generate a prediction ML model through ML between the bottom CDs and the features. Also, the PPC based on ML may generate an ACI target having a maximum process window by using the prediction ML model and may generate the second layout corresponding to the generated ACI target through an ADI retarget.

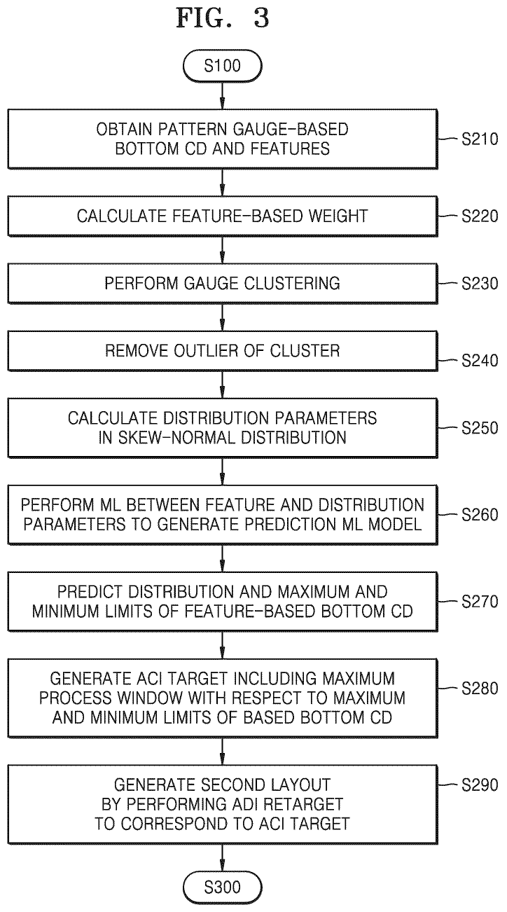

The second layout generated through the PPC based on ML may be a layout of ADI. In other words, the second layout may be a target layout of photoresist (PR) which is to be obtained in the ADI. The ADI may denote inspection of PR patterns formed on a wafer after a photo process, and the photo process may include an exposure process and a development process. The PPC based on ML is described in more detail with reference to FIGS. 3 to 8.

Subsequently, a third layout may be generated by performing OPC on the second layout in operation S300. That is, the third layout may be an OPC-performed layout of patterns on a mask.

For reference, to form a target pattern on a substrate such as a wafer, the patterns on the mask and the layout of the patterns have to be generated. That is, the target pattern on the wafer may be formed by transferring the patterns on the mask to the wafer through an exposure process. Based on a characteristic of the exposure process, the target pattern on the wafer may differ from the shape of each of the patterns on the mask. Also, the pattern on the mask may be reduced, projected, and transferred onto the wafer and may thus have a size which is greater than that of the target pattern on the wafer.

Furthermore, as a pattern is micronized, an optical proximity effect (OPE) caused by an influence between adjacent patterns may occur in performing an exposure process, and to overcome such a problem, OPC for preventing the OPE from occurring may be performed by correcting the layout of the pattern on the mask.

The OPC will be overall described below. The OPC may be divided into two OPCs, and in this case, one of the two OPCs may be a rule-based OPC and the other may be a simulation-based or model-based OPC. General OPC may include a method of adding sub-lithographic features called serifs to a corner of a pattern, or a method of adding sub-resolution assist features (SRAFs) such as scattering bars, in addition to deformation of a layout of a pattern.

The OPC may first prepare basic data for the OPC. Here, the basic data may include data of shapes of patterns of a sample, positions of the patterns, the kind of measurement such as measurement of a space or a line of a pattern, and a basic measurement value. Also, the basic data may include information about a refractive index, a dielectric constant, and a thickness of PR and may include a source map of the shape of an illumination system. However, the basic data is not limited to the data described above.

After the basic data is prepared, an optical OPC model may be generated. An operation of generating the optical OPC model may include optimization of a defocus stand (DS) position and a best focus (BF) position in an exposure process. Also, the operation of generating the optical OPC model may include an operation of generating an optical image, based on diffraction of light or an optical state of exposure equipment. However, the operation of generating the optical OPC model is not limited to the above descriptions. For example, the operation of generating the optical OPC model may include various details associated with an optical phenomenon in the exposure process.

After the optical OPC model is generated, an OPC model for PR may be generated. An operation of generating the OPC model for PR may include optimization of a threshold value of PR. Here, the threshold value of PR may denote a threshold value where chemical change occurs in the exposure process, and for example, the threshold value may be defined as intensity of exposure light. The operation of generating the OPC model for PR may include an operation of selecting an appropriate model form from among a plurality of PR model forms.

A generic name for an optical OPC model and an OPC model for PR may generally be an OPC model. After the OPC model is generated, an OPC-performed layout may be generated by performing a simulation using the OPC model. The third layout may correspond to the OPC-performed layout.

Subsequently, by performing optical rule check (ORC) on the OPC-performed layout, the final OPC-performed layout may be determined. Here, the ORC may include calculation of root mean square (RMS) on a CD error, calculation of an edge placement error (EPE), inspection of a pinch error, and inspection of a bridge error. Items inspected in the ORC are not limited to the items described above.

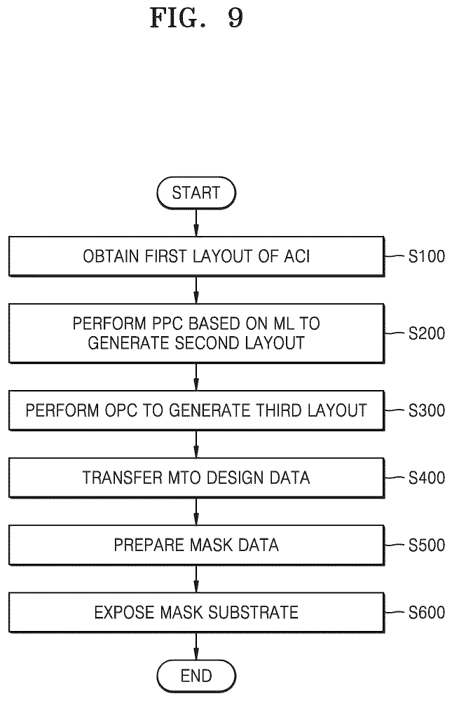

Continuously, the final OPC-performed layout may be transferred as MTO design data to a mask team, a mask may be manufactured, and a pattern may be formed on a wafer by performing a photo process and an etching process by using the mask, thereby manufacturing a semiconductor device. A method of manufacturing a mask is described in more detail with reference to FIG. 9.

The OPC method in some implementations may include a PPC method based on ML. Also, the PPC method based on ML may include an operation of generating an ACI target where a process window is maximized through ML, based on a bottom CD and features, and moreover, may include an operation of generating a layout (for example, the second layout of the ADI) based on the generated ACI target. Accordingly, the OPC method in some implementations may secure matching and robustness to a defect of an ACI CD (particularly, an ACI bottom CD) based on the PPC method based on ML. Here, the process window may be the same concept as a process margin, and hereinafter, a generic name for the process window and the process margin may be a process window.

The OPC method in some implementations may predict the maximum limit and the minimum limit of the pattern-based ACI bottom CD, generate the ACI target where the process window is maximized, and generate the second layout of the ADI corresponding to the ACI target through the ADI retarget based on the PPC method based on ML. Also, the OPC method in some implementations may generate the third layout (i.e., the OPC-performed layout) of the pattern on the mask through the OPC performed on the second layout of the ADI. In the ACI CD (for example, a high aspect ratio contact (HARC)), the OPC method in some implementations may generate the second layout, which may secure matching and robustness to a defect of the ACI bottom CD, and an OPC-performed layout based thereon.

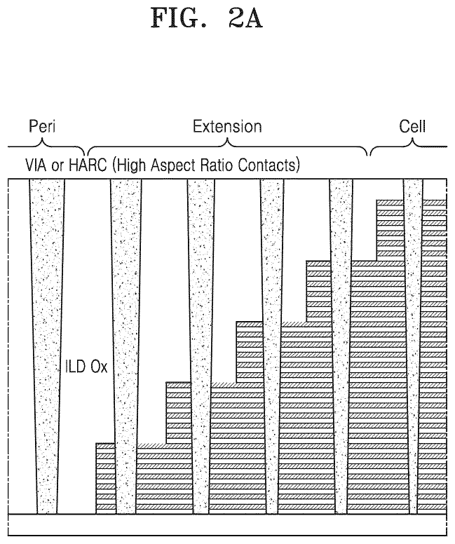

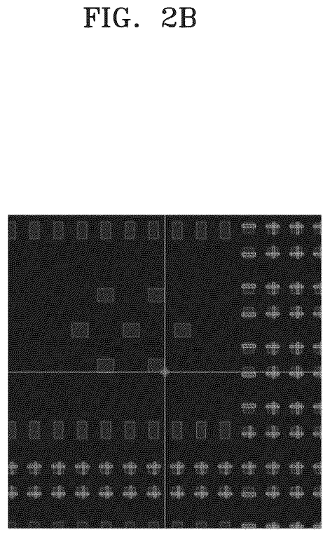

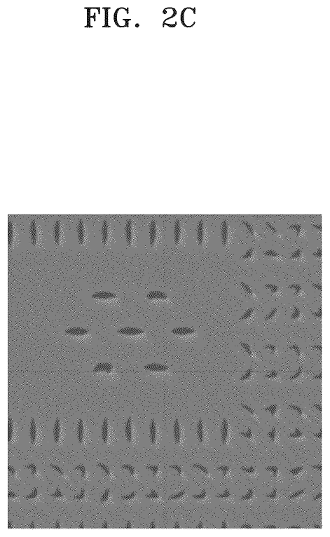

FIGS. 2A to 2C are an example cross-sectional view of an HARC layer of an extension region of a VNAND flash memory, an example plan view of an ADI target of the HARC layer, and an example SEM photograph of an ACI bottom CD of the HARC layer.

Referring to FIGS. 2A to 2C, memories may be vertically stacked for enhancing the degree of integration of a NAND flash memory, and as illustrated in FIG. 2A, HARC layers may be provided in an extension region of a VNAND flash memory or vertical channels of a high aspect ratio (HAR) may be provided in a cell region. However, as an aspect ratio increases progressively, the difference between an ACI top CD on and an ACI bottom CD under a through hole for the HARC layer or a vertical channel may progressively increase. For example, the plan view of FIG. 2B shows a target of an ADI on a through hole of the HARC layer and may correspond to the top CD of the ACI. Also, FIG. 2C shows an ACI bottom CD obtained through SEM measurement after grinding the through hole of the HARC layer up to the bottom. Comparing FIG. 2B with FIG. 2C, it may be seen that there is a large difference between the ACI top CD and the ACI bottom CD thereunder. For reference, the ADI target of FIG. 2B is illustrated based on a drawing file of a graphic design system (GDS) format.

Also, in an etching process for the through hole of the HAR layer, due to a defect caused by degradation in variation of the bottom CD, the difficulty in forming a through hole may increase. A defect of an etching process for the through hole of the HAR layer, for example, may include a not-open (NOP) defect, where the through hole is not sufficiently etched up to the bottom, or a defect where the through hole is excessively punched.

In terms of maximizing a process window needed for a semiconductor process, the OPC method in some implementations may implement PPC so that a process window is maximized in a bottom surface, in addition to a top surface of a vertical structure of HAR. In the OPC method, the PPC method based on ML may perform ML on the distribution of ACI bottom CDs based on features of a certain pattern (for example, a pattern size, a peripheral pattern density, and a lower structure) and may calculate the distribution, the maximum limit, and the minimum limit of bottom CDs based on each feature. The ACI target may be set so that the maximum limit and the minimum limit of the bottom CD is farthest away from the maximum limit and the minimum limit each allowed by a process window, and thus, robustness to a bottom defect may be secured and a process window may be maximized.

FIG. 3 is a flowchart illustrating in more detail an example operation of performing PPC based on ML, in the OPC method of FIG. 1. FIG. 3 will be described in conjunction with FIG. 1, and descriptions given above with reference to FIGS. 1 to 2C will be briefly given or are omitted.

Referring to FIG. 3, in the OPC method in some implementations, operation S200 of performing PPC based on ML (hereinafter, referred to as a PPC method based on ML for convenience) may first obtain pattern gauge-based bottom CDs and features in operation S210. The pattern gauge-based bottom CD may be an ACI bottom CD and may be obtained through large-scale measurement of patterns on a wafer. Here, a gauge or a pattern gauge may denote a predetermined pattern used in measurement or a pattern for measurement.

Also, the pattern gauge-based features may be obtained by extracting patterns of a first layout obtained previously. As described above, the first layout may be a layout of ACI. For example, one or more features may be extracted by pattern gauges from patterns in an image of the first layout. Also, the same kind of features may be extracted by pattern gauges, or different kinds of features may be extracted. Features may include a feature of each of patterns and a feature associated with influences of adjacent patterns on each pattern in etching. Here, a feature of each pattern may denote, for example, the size and the shape of a corresponding pattern.

In more detail, features of patterns may be digitized as some items as follows. For example, features of each pattern may be digitized and extracted as a tone, a direction, a length, a density, a sublayer, a space and a width of a segment adjacent thereto in a normal direction, information about a next/previous segment, and harmonics. However, the kinds of features are not limited to the items described above.

Furthermore, an operation of obtaining pattern gauge-based features from the first layout may include an operation of tagging features, extracted from each of patterns, to a corresponding pattern. That is, influences of features on each pattern in etching may be information and may be assigned to a corresponding pattern.

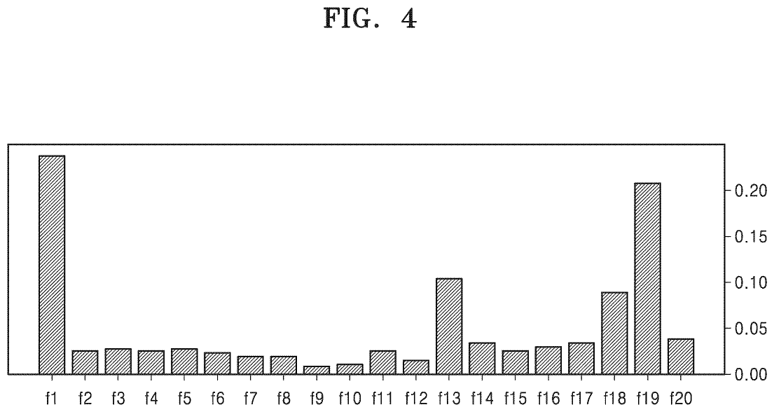

Subsequently, a feature-based weight affecting a bottom CD may be calculated in operation S220. The feature-based weight (for example, a feature-based weight corresponding to a bottom CD) may be calculated by learning the relationship between the bottom CD and features through a random forest (RF) algorithm. An operation of calculating a feature-based weight may be performed for quickly and effectively performing a gauge clustering operation later. In some implementations, the operation S220 of calculating the feature-based weight may be omitted. The operation S220 of calculating the feature-based weight is described in more detail with reference to FIG. 4.

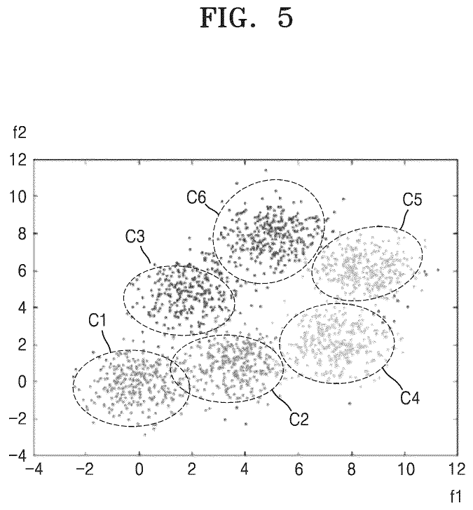

Subsequently, a gauge clustering operation of grouping and classifying pattern gauges including similar features may be performed in operation S230. As the operation of calculating weights of features is performed, clustering may be performed by similar pattern gauge units based on features to which weights are applied. In the PPC method based on ML in some implementations, a balanced iterative reducing and clustering using hierarchies (BIRCH) clustering algorithm may be used for efficiently performing clustering on large-scale data. The operation S230 of performing the gauge clustering operation is described in more detail with reference to FIG. 5.

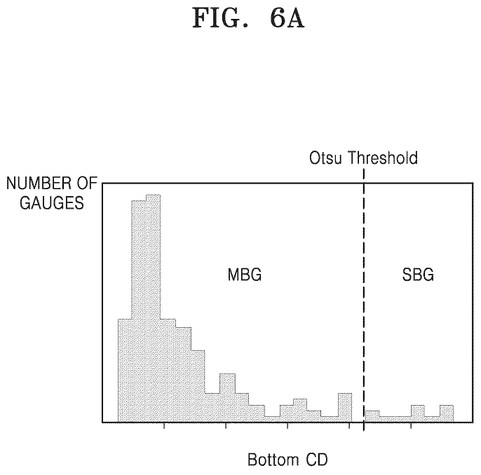

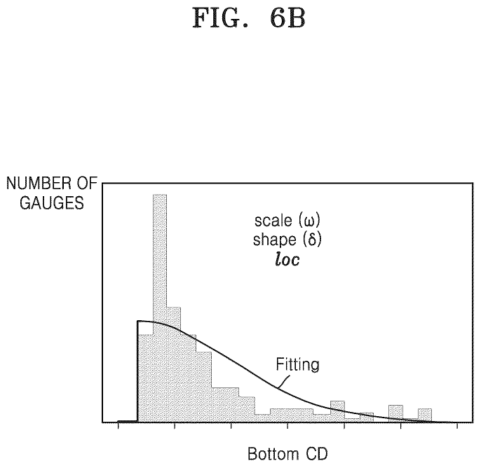

After the gauge clustering operation is performed, an outlier of each cluster may be removed in operation S240. A distribution of bottom CDs in each cluster may be represented as a skew-normal distribution. Furthermore, an outlier which is provided at a low probability in each cluster may cause a considerable error in subsequent learning and calculating of distribution parameters. Therefore, in the PPC method based on ML in some implementations, an outlier may be removed before fitting a distribution of bottom CDs to a skew-normal distribution. An operation of removing the outlier may be performed by using, for example, an Otsu-segmentation algorithm. In some implementations, the operation S240 of removing the outlier may be omitted. The operation S240 of removing the outlier is described in more detail with reference to FIG. 6A.

Continuously, a skew-normal distribution or a skew-normal distribution graph may be obtained by fitting a distribution of bottom CDs in each cluster, and distribution parameters may be calculated in the skew-normal distribution in operation S250. The distribution-parameters may denote parameters defining the skew-normal distribution. In other words, when the skew-normal distribution is generated, the distribution parameters may be calculated in the skew-normal distribution, and when there are the distribution parameters, a corresponding skew-normal distribution may be generated. In the PPC method based on ML in some implementations, the distribution parameters may include, for example, a location, a scale, and a shape. For reference, a location, a scale, and a shape which are the distribution parameters of the skew-normal distribution may correspond to an average, a standard deviation, and skewness which are distribution parameters of a normal distribution. The operation S250 of calculating the distribution parameters is described in more detail with reference to FIG. 6B.

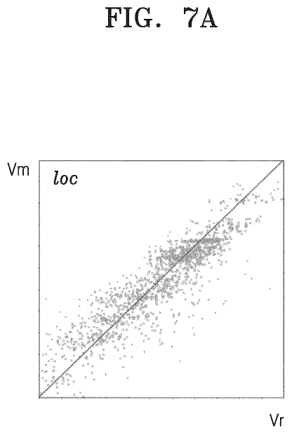

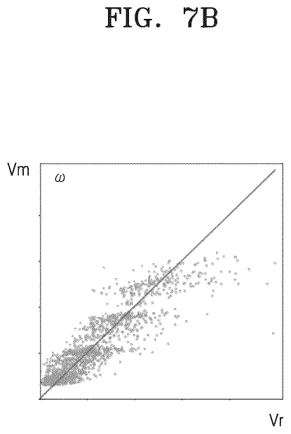

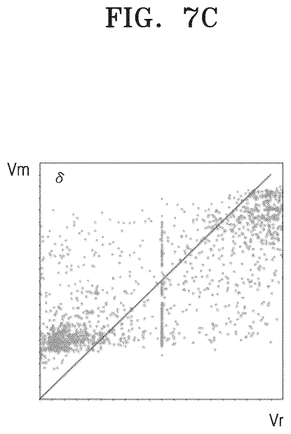

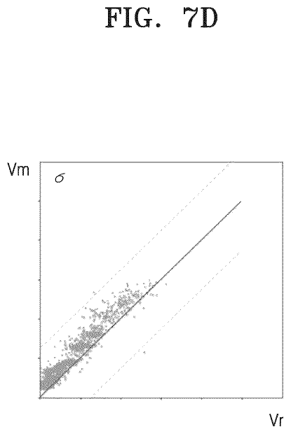

After the distribution parameters are calculated, a prediction ML model may be generated by performing ML between features and distribution parameters in each cluster in operation S260, and the distribution, the maximum limit, and the minimum limit of pattern-based bottom CDs may be predicted by using the prediction ML model in operation S270. The prediction ML model may predict a distribution where bottom CDs based on features of each pattern is expected. In other words, when features of each pattern is input to the prediction ML model, the prediction ML model may predict a distribution of bottom CDs of a corresponding pattern and the maximum limit and the minimum limit of the bottom CDs. The accuracy of prediction by the prediction ML model is described with reference to FIGS. 7A to 7D.

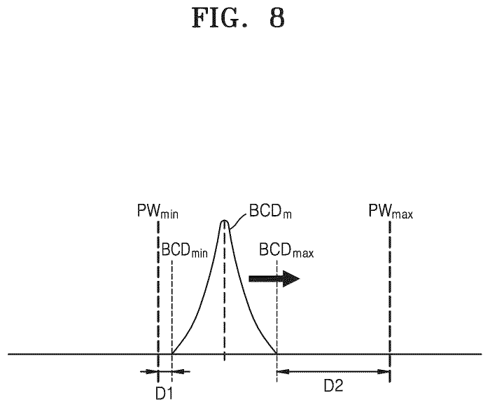

Continuously, an ACI target including a maximum process window may be generated based on the maximum limit and the minimum limit of the bottom CDs predicted by the prediction ML model in operation S280. For example, the ACI target may be generated so that a smaller value of a first difference value between the minimum limit of the bottom CD and the minimum limit of the maximum process window and a second difference value between the maximum limit of the bottom CD and the maximum limit of the maximum process window is maximized. An operation of generating the ACI target is described with reference to FIG. 8.

After the ACI target is generated, a second layout may be generated by performing an ADI retarget operation to correspond to the ACI target in operation S290. That is, the first layout may be corrected to correspond to the ACI target, and the second layout of the ADI may be generated based on the corrected first layout. For example, based on the ACI target and the corrected first layout corresponding thereto, the second layout of the ADI may be generated by adjusting internal portions of patterns such as sizes and shapes of the patterns. An operation of generating the second layout of the ADI may correspond to the ADI retarget operation, and moreover, as described above with reference to FIG. 1, the second layout of the ADI may be used as an input of subsequent OPC. Furthermore, the operation of generating the second layout of the ADI or the ADI retarget operation may repeat an operation of correcting a layout of ADI so as to be approximate to the ACI target, and when the ACI target is converged, correction of the layout of the ADI may end and a layout of corresponding ADI may be determined and generated as the second layout of the ADI.

The PPC method based on ML in some implementations may be used for predicting and correcting ACI skew which occurs due to an etching process after a photo process. Fundamentally, the PPC method based on ML may compress information about a layout to reduce the information to several to hundreds of features and may thus predict a correlation between a design layout and ACI through the prediction ML model, based on the size of a pattern, a location with a peripheral pattern, a long range, and a lower structure effect. Subsequently, a retarget operation may be performed on the layout of the ADI to correspond to the ACI target, thereby improving a variation and matching of ACI CDs. Also, the PPC method based on ML may perform variation prediction and ACI targeting on an ACI top CD and an ACI bottom CD by using measurement data of the ACI bottom CD as well as measurement data of the ACI top CD in a vertical structure of HAR. Therefore, matching and robustness to an ACI CD defect (particularly, a bottom CD defect of the vertical structure of HAR) may be secured in an etching process, and thus, a defect problem of a bottom CD may be effectively solved.

FIG. 4 is a graph of feature-based weights for describing an example operation of calculating feature-based weights, in the PPC method based on ML of FIG. 3. The x axis of the graph represents the kinds of features and the y axis represents weights, without a unit. FIG. 4 will be described in conjunction with FIG. 3, and descriptions given above with reference to FIGS. 1 to 3 will be briefly given or are omitted.

Referring to FIG. 4, all features of a pattern may not have equal significance on a bottom CD. In other words, some features may largely affect the bottom CD, but some other features may hardly affect the bottom CD. Therefore, weights based on significance may be respectively assigned to features, and thus, a clustering operation may be quickly and effectively performed.

When regression is performed by using an RF algorithm included in an ML technique so as to determine the relationship between the bottom CD and features (a peripheral pattern density, a lower structure, and a pattern size) of each pattern gauge, the significance of each feature on the bottom CD may be calculated.

For reference, the RF algorithm may be a kind of ensemble algorithm which may group several decision trees to avoid overfitting, an average of trees which well performs prediction (capable of overfitting) may be calculated, and thus, overfitting may be reduced. The RF algorithm may be configured so that one decision tree is generated by randomly selecting only some features from among all features, and by repeating such a process a plurality of times desired by a user, several decision trees are generated. Also, a value which is the most calculated among prediction values determined by several decision trees may be determined as the final prediction value. Generally, the RF algorithm may be used in all of classification and regression, may be easy to use on missing data, and may be effective to processing of massive data. Also, an overfitting problem of increasing noise of a model may be avoided, model accuracy may be enhanced, and a relatively significant parameter may be selected and ranked in a classification model.

As illustrated in FIG. 4, the significance of twenty features is illustrated by the height of a bar graph. That is, as the height of a bar graph increases, it may be considered that the influence of a corresponding feature on a bottom CD is large. For example, in the graph of FIG. 4, it may be determined that influences of a first feature f1, a thirteenth feature f13, an eighteenth feature f18, and a nineteenth feature f19 on a bottom CD are large. Therefore, a clustering operation may be performed on a group of similar gauges each, based on features having high significance, and thus, a cluster sharing relatively significant features may be generated. Also, features which hardly affect a bottom CD may be excluded from clustering, and thus, a clustering operation may be more quickly performed.

Furthermore, features may represent a feature of a pattern or a relationship with adjacent patterns, and moreover, the features may be digitized and used as a certain value in a clustering operation. Accordingly, features used in a gauge clustering operation may be referred to as feature values.

FIG. 5 is a gauge distribution graph of features for describing an example operation of performing gauge clustering in the PPC method based on ML of FIG. 3. The x axis and the y axis of the graph represent weights of two features. FIG. 5 will be described in conjunction with FIG. 3, and descriptions given above with reference to FIGS. 1 to 4 will be briefly given or are omitted.

Referring to FIG. 5, a gauge distribution graph may be illustrated by features included in gauges, and particularly, may be illustrated by features used in gauge clustering. In FIG. 5, for convenience, the gauge distribution graph is two-dimensionally illustrated based on two features, but in a case where three or more features are used in gauge clustering, the gauge distribution graph may be three or more-dimensionally illustrated.

In the graph of FIG. 5, a number of gauges may be classified into six clusters through gauge clustering. For example, in the graph of FIG. 5, a number of gauges may be classified into a first cluster C1 where a center portion corresponds to (0, 0) of a first feature f1 and a second feature f2, a second cluster C2 where a center portion corresponds to (4, 1) of the first feature f1 and the second feature f2, a third cluster C3 where a center portion corresponds to (2, 4) of the first feature f1 and the second feature f2, a fourth cluster C4 where a center portion corresponds to (8, 2) of the first feature f1 and the second feature f2, a fifth cluster C5 where a center portion corresponds to (9, 6) of the first feature f1 and the second feature f2, and a sixth cluster C6 where a center portion corresponds to (5, 8) of the first feature f1 and the second feature f2.

As a detailed example, in the PPC method based on ML in some implementations, million or more of gauges may be classified into thousands of clusters through gauge clustering. As described above, a BIRCH clustering algorithm may be used for efficiently performing a clustering operation on large-scale data. For reference, the BIRCH clustering algorithm may be a tree-based algorithm suitable for a large-scale data set, and because the BIRCH clustering algorithm is based on a tree, a sample may not be stored along with a generated model and may be quickly allocated to a cluster. However, the BIRCH clustering algorithm may be based on a tree, and thus, when the number of functions is 20 or less, the BIRCH clustering algorithm may be used.

FIGS. 6A and 6B are graphs of bottom CDs for describing an example operation of removing an outlier and an example operation of calculating distribution parameters, in the PPC method based on ML of FIG. 3. In each of the graphs, the x axis represents bottom CDs and the y axis represents the number of pattern gauges. FIGS. 6A and 6B will be described in conjunction with FIG. 3, and descriptions given above with reference to FIGS. 1 to 3 will be briefly given or are omitted.

Referring to FIG. 6A, a distribution of bottom CDs may be checked in each cluster, and as illustrated in FIG. 6A, the distribution may show the form of a skew-normal distribution having skewness instead of a normal distribution. Therefore, a distribution of bottom CDs of each cluster may be fundamentally regarded as a skew-normal distribution, and three parameters (a location, a scale, and a shape) of the skew-normal distribution may be calculated. Furthermore, as described above, an outlier in each cluster may be removed for preventing the occurrence of an error in learning of subsequent distribution parameters. The outlier may be systemically removed by using the Otsu-segmentation algorithm.

In FIG. 6A, an Otsu threshold value is illustrated by a dashed line, a main-bar graph (MBG) may be located at the left of the dashed line, and a sub-bar graph (SBG) may be located at the right of the dashed line. An SBG portion at the right of the dashed line may be removed by the Otsu-segmentation algorithm. That is, in a total bottom CD distribution of each cluster, an SBG portion corresponding to the outlier may be removed by the Otsu-segmentation algorithm, and only a bottom CD distribution of an MBG portion may remain.

Referring to FIG. 6B, a skew-normal distribution graph may be obtained by fitting a bottom CD distribution of an MBG portion of each cluster. In FIG. 6B, the solid line illustrated by ‘Fitting’ may correspond to a fitting line, and a portion surrounded by the fitting line may correspond to the skew-normal distribution graph. When the skew-normal distribution graph is obtained, distribution parameters corresponding thereto may be calculated. That is, three distribution parameters such as a location “loc”, a scale “ω”, and a shape “δ” may be calculated from the skew-normal distribution graph.

FIGS. 7A to 7D are example graphs showing prediction values of distribution parameters based on a prediction ML model in the PPC method based on ML of FIG. 3 and real values of distribution parameters. In each of the graphs, the x axis represents a real value “Vr”, the y axis represents a prediction value “Vm”, and a unit of each of the real value and the prediction value may be an arbitrary unit. FIGS. 7A to 7D will be described in conjunction with FIG. 3, and descriptions given above with reference to FIGS. 1 to 6b will be briefly given or are omitted.

Referring to FIGS. 7A to 7D, as described above, when distribution parameters are calculated, a prediction ML model may be generated by performing ML on a relationship between an average feature value of a cluster and distribution parameters of a bottom CD distribution. Furthermore, the average feature value may be calculated by averaging feature values of the same features of gauges included in the cluster. In more detail, for example, a first cluster may include first to fifth gauges G1 to G5, and each of the first to fifth gauges G1 to G5 may include a first feature f1, a second feature f2, and a third feature f3. Also, based on clustering of the first cluster, digits of features (i.e., feature values) of each of the first to fifth gauges G1 to G5 may be similar to one another. For example, the first to third feature values of the first gauge G1 may be (2.0, 3.4, 5.2), the first to third feature values of the second gauge G2 may be (2.1, 3.3, 5.3), the first to third feature values of the third gauge G3 may be (1.9, 3.4, 5.3), the first to third feature values of the fourth gauge G4 may be (2.1, 3.5, 5.2), and the first to third feature values of the fifth gauge G5 may be (2.0, 3.3, 5.1). The first to fifth gauges G1 to G5 may have similarity within a range of 0.2 with respect to each of the first feature f1, the second feature f2, and the third feature f3. Furthermore, first feature values of the first features f1 may not accurately match therebetween, and thus, in the first cluster, when the first feature values of the first features f1 of the first to fifth gauges G1 to G5 are averaged, an average first feature value “(2.0+2.1+1.9+2.1+2.0)/5=2.0” may be calculated. Likewise, an average second feature value of the second features f2 and an average third feature value of the third features f3 may be calculated.

Furthermore, a prediction ML model may be generated through ML, and then, when feature values of each pattern are input to the prediction ML model, the prediction ML model may predict and output a bottom CD distribution which is expected to be based on a bottom CD of a corresponding pattern. Also, the prediction ML model may predict the maximum limit and the minimum limit of a bottom CD along with a bottom CD distribution of a corresponding pattern.

Also, when the prediction ML model predicts a bottom CD distribution, the prediction ML model may calculate distribution parameters in a predicted bottom CD distribution graph. In other words, distribution parameters and a bottom CD distribution of a corresponding pattern may be predicted by using the prediction ML model. FIGS. 7A to 7C each show a real value and a prediction value based on the prediction ML model with respect to distribution parameters of a location “loc”, a scale “ω”, and a shape “δ”. As seen in FIGS. 7A and 7B, in the distribution parameters of the location “loc” and the scale “ω”, it may be seen that a real value and a prediction value concentrate on a one-dimensional linear portion and matches to the degree.

In the distribution parameter of the shape “δ” of FIG. 7C, a real value and a prediction value may be arranged regardless of a one-dimensional line. However, based on a graph of standard deviation “σ” of FIG. 7D, it may be seen that a real value matches a prediction value within a confidence range.

A relationship expressed as the following Equation 1 may be established between the standard deviation “σ”, the scale “ω”, and the shape “δ”.

$${σ}^{2} = {ω}^{2} * ( 1 - 2 {δ}^{2} / π ) \qquad ( 1 )$$

Also, the standard deviation of a cluster may be calculated based on distribution parameters predicted by the prediction ML model with respect to each cluster, and when accuracy is evaluated by comparing with a real standard deviation, root mean square (RMS)=1.4 nm, max error (ME)=5 nm, and R2=0.87 may be calculated, whereby it may be seen that prediction values based on the prediction ML model have high accuracy. Here, R2 may denote a regression determination coefficient “R2”.

Also, a maximum/minimum interval (min/max interval) of bottom CDs have been predicted at various confidence levels based on a bottom CD distribution of each cluster predicted by the prediction ML model, and accuracy is shown to be almost equal to a confidence level.

FIG. 8 is a graph for describing an example operation of predicting a bottom CD distribution and maximum and minimum limits and an example operation of generating an ACI target, in the PPC method based on ML of FIG. 3. FIG. 8 will be described in conjunction with FIG. 3, and descriptions given above with reference to FIGS. 1 to 7d will be briefly given or are omitted.

Referring to FIG. 8, BCD may denote a bottom CD, and a normal distribution graph of the solid line may be a distribution graph BCDm of a bottom CD, predicted by the prediction ML model, with respect to a certain pattern. Also, both thick dashed lines of an outer portion may respectively represent the maximum limit PWmax and the minimum limit PWmin of a process window, and thin dashed lines at both ends of the distribution graph BCDm of the bottom CD may respectively represent the maximum limit BCDmax and the minimum limit BCDmin of the bottom CD.

As described above, the prediction ML model may be generated through ML, and then, when a feature value of each pattern is input to the prediction ML model, the prediction ML model may predict and output the distribution graph BCDm of the bottom CD. In FIG. 8, both ends of the distribution graph BCDm of the bottom CD have been calculated or set to the maximum limit BCDmax and the minimum limit BCDmin of the bottom CD, but in some implementations, the maximum limit BCDmax and the minimum limit BCDmin of the bottom CD may be more widely set or calculated.

Furthermore, when the maximum limit BCDmax or the minimum limit BCDmin of the bottom CD approaches the maximum limit and the minimum limit allowed in a semiconductor process (i.e., the maximum limit PWmax and the minimum limit PWmin of the process window), a defect may occur. Accordingly, an ACI target has to be set so that the maximum limit BCDmax or the minimum limit BCDmin of the bottom CD is farthest away from the maximum limit PWmax and the minimum limit PWmin of the process window.

For example, when the distribution graph BCDm of the bottom CD and the maximum limit BCDmax and the minimum limit BCDmin of the bottom CD are calculated by the prediction ML model, as illustrated in FIG. 8, a first difference value D1, which is a difference between the minimum limit PWmin of the process window and the minimum limit BCDmin of the bottom CD, and a second difference value D2, which is a difference between the maximum limit PWmax of the process window and the maximum limit BCDmax of the bottom CD, may be calculated. Subsequently, the ACI target may be generated so that a smaller value of the first difference value D1 and the second difference value D2 is maximized, and thus, the process window may be maximized.

In FIG. 8, as illustrated by a thick graph, by moving the distribution graph BCDm of the bottom CD to the right, the first difference value D1 may increase, and thus, the process window may be maximized. An operation of moving the distribution graph BCDm of the bottom CD to the right may correspond to an operation of generating the ACI target and an ADI retarget operation of targeting to the ACI target.

FIG. 9 is a flowchart schematically illustrating an example process of a method of manufacturing a mask by using a PPC method based on ML. FIG. 9 will be described in conjunction with FIGS. 1 and 3, and descriptions given above with reference to FIGS. 1 to 8 will be briefly given or are omitted.

Referring to FIG. 9, the method of manufacturing a mask by using the PPC method based on ML (hereinafter simply referred to as a mask manufacturing method) in some implementations may sequentially perform operation S100 of obtaining a first layout, operation S200 of performing PPC based on ML, and operation S300 of obtaining a third layout. The operation S100 of obtaining the first layout to the operation S300 of obtaining the third layout may be the same as the descriptions of the OPC method of FIG. 1. Also, as described in the PPC method based on ML of FIG. 3, the operation S200 of performing the PPC based on ML may include operation S210 of obtaining pattern gauge-based bottom CD and features, operations S220 to S280, and operation S290 of generating a second layout. Furthermore, the third layout may correspond to an OPC-performed layout of each of patterns on a mask, and moreover, may correspond to a final OPC-performed layout which has undergone ORC.

Continuously, the final OPC-performed layout image may be transferred as MTO design data to a mask manufacturing team in operation S400. Generally, MTO may denote that final mask data obtained through OPC is transferred to the mask manufacturing team and manufacturing of a mask is requested. Therefore, the MTO design data may be substantially the same as data of the final OPC-performed layout image obtained through the OPC. The MTO design data may have a graphic data format used in electronic design automation (EDA) software and the like. For example, the MTO design data may have a data format such as graphic data system II (GDS2) or open artwork system interchange standard (OASIS).

Subsequently, MDP may be performed in operation S500. The MDP may include, for example, i) format conversion called fracturing, ii) augmentation such as a bar code for mechanical readout, a standard mask pattern for inspection, and job deck, and iii) automatic and passive verification. Here, the job deck may denote an operation of generating a text file associated with a series of instructions, such as arrangement information about multiple mask files, a reference dose, and an exposure speed or method.

The format conversion (i.e., fracturing) may denote an operation of segmenting the MTO design data by regions to convert the MTO design data into a format for electron beam writers. The fracturing may include, for example, data manipulation such as scaling, sizing of data, rotation of data, pattern reflection, and color conversion. In a conversion operation based on fracturing, data corresponding to a number of systematic errors occurring in the middle of being transferred as an image on a wafer from design data may be corrected. A data correction process on the systematic errors may be referred to as mask process correction (MPC), and for example, may include an operation of increasing the precision of pattern arrangement and line width adjustment called CD adjustment. Therefore, the fracturing may contribute to the enhancement of quality of the final mask and may be a process which is previously performed for the MPC. Here, the systematic errors may be caused by distortion occurring in an exposure process, a mask development and etching process, and a wafer imaging process.

The MDP may include the MPC. The MPC, as described above, may denote a process of correcting an error (i.e., a systematic error) occurring in the exposure process. Here, the exposure process may be a concept which overall includes electron beam writing, development, etching, and bake. Furthermore, data processing may be performed before the exposure process. The data processing may be a preprocessing process on mask data and may include grammar check and exposure time prediction on the mask data.

After the mask data is prepared, a mask substrate may be exposed based on the mask data in operation S600. Here, the exposure may denote, for example, electron beam writing. Here, the electron beam writing may be performed by, for example, a gray writing process using a multi-beam mask writer (MBMW). Also, the electron beam writing may be performed by using a variable shape beam (VSB) writer.

After an MDP operation is performed, an operation of converting the mask data into pixel data may be performed before an exposure process. The pixel data may be data which is directly used in real exposure and may include data of shape which is an exposure target and data of dose allocated thereto. Here, the data of shape may be bit-map data obtained through conversion of shape data, which is vector data, through rasterization.

After the exposure process, a mask may be finished by performing a series of processes. The processes may include, for example, processes such as development, etching, and cleaning. Also, a series of processes for manufacturing a mask may include a measurement process and a defect inspection process or a defect repair process. Also, a pellicle coating process may be included in the processes. Herein, the pellicle coating process may denote a process which attaches a pellicle for protecting a mask from subsequent pollution during an available lifetime duration of the mask and transfer of the mask when it is determined through final cleaning an inspection that there are no pollution particles or chemical smears.

The mask manufacturing method in some implementations may include a PPC method based on ML, and the PPC method based on ML may generate an ACI target where a process window is maximized through ML by using a bottom CD and features, and then, may generate a second layout of ADI by performing an ADI retarget operation corresponding thereto. Accordingly, the mask manufacturing method may generate a mask layout (i.e., an OPC-performed layout) where matching is high and a process window is maximized, based on the PPC method and the OPC method based thereon. As a result, the mask manufacturing method may manufacture a mask having reliability, based on a mask layout where a process window is maximized, and moreover, may manufacture a semiconductor device having reliability by using the mask.

Hereinabove, some implementations have been described in the drawings and the specification, but it may be understood by those of ordinary skill in the art that various modifications and other equivalent implementations may be implemented from the concepts disclosed herein. Accordingly, the spirit and scope of the concepts disclosed herein may be defined based on the spirit and scope of the following claims.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

While the concepts disclosed herein have been particularly shown and described with reference to implementations thereof, it will be understood that various changes in form and details may be made therein without departing from the spirit and scope of the following claims.

What is claimed is:

1. A process proximity correction (PPC) method based on machine learning (ML), the PPC method comprising:
obtaining a pattern gauge-based bottom critical dimension (CD) through measurement of patterns on a wafer and obtaining pattern gauge-based features from a first layout corresponding to the patterns on the wafer;
performing a gauge clustering operation of grouping and classifying pattern gauges including similar features;
calculating distribution parameters in a skew-normal distribution of the pattern gauge-based bottom CD in each cluster;
performing ML between the distribution parameters and a feature in each cluster to generate a prediction ML model;
predicting a distribution, a maximum limit, and a minimum limit of the pattern gauge-based bottom CD based on a feature by using the prediction ML model;
generating an after cleaning inspection (ACI) target including a maximum process window with respect to the maximum limit and the minimum limit of the pattern gauge-based bottom CD; and
generating a second layout by performing an after development inspection (ADI) retarget operation to correspond to the ACI target.

2. The PPC method of claim 1, further comprising, before performing the gauge clustering operation, calculating a feature-based weight based on a correlation between the bottom CD and the feature,
wherein the performing of the gauge clustering operation comprises performing the gauge clustering operation by using features to which the feature-based weight is applied.

3. The PPC method of claim 2, wherein the calculating of the feature-based weight uses a random forest (RF) algorithm, and
the performing of the gauge clustering operation uses a balanced iterative reducing and clustering using hierarchies (BIRCH) algorithm.

4. The PPC method of claim 1, wherein the calculating of the distribution parameters comprises removing an outlier of the cluster and obtaining the skew-normal distribution through fitting.

5. The PPC method of claim 4, wherein the removing of the outlier is performed by using an Otsu-segmentation algorithm.

6. The PPC method of claim 1, wherein the distribution parameters comprise a location, a scale, and a shape respectively corresponding to an average, a standard deviation, and skewness in a normal distribution.

7. The PPC method of claim 1, wherein the generating of the ACI target comprises generating the ACI target so that a smaller value of a first difference value between a maximum limit value of the bottom CD and a maximum limit value of the process window and a second difference value between a minimum limit value of the bottom CD and a minimum limit value of the process window is maximized.

8. The PPC method of claim 1, wherein the generating of the prediction ML model comprises calculating an average feature value of each of features and performing ML between the average feature value and the distribution parameters, in each cluster.

9. The PPC method of claim 1, wherein the bottom CD comprises a bottom CD of ACI,
the first layout comprises a layout of ACI, and
the second layout comprises a layout of ADI.

10. The PPC method of claim 1, wherein the second layout is used in optical proximity correction (OPC).

11. An optical proximity correction (OPC) method, comprising:
obtaining a first layout of after cleaning inspection (ACI) corresponding to patterns on a wafer;
performing progress proximity correction (PPC) based on machine learning (ML) to generate a second layout of after development inspection (ADI); and
performing OPC on the second layout to generate a third layout,
wherein the performing of the PPC based on ML comprises obtaining a pattern gauge-based bottom critical dimension (CD) and features, generating a prediction ML model, based on the pattern gauge-based bottom CD and features, and generating an ACI target including a maximum process window with respect to a maximum limit and a minimum limit of the pattern gauge-based bottom CD predicted through the prediction ML model.

12. The OPC method of claim 11, wherein the performing of the PPC based on ML comprises:
obtaining a pattern gauge-based bottom CD of ACI through measurement of patterns on the wafer and obtaining the pattern gauge-based features from the first layout;
performing a gauge clustering operation of grouping and classifying pattern gauges including similar features;
calculating distribution parameters in a skew-normal distribution of the pattern gauge-based bottom CD in each cluster;
generating the prediction ML model through ML between the distribution parameters and an average feature value in each cluster;
predicting a distribution, a maximum limit, and a minimum limit of the pattern gauge-based bottom CD based on a feature by using the prediction ML model;
generating the ACI target including the maximum process window with respect to the maximum limit and the minimum limit of the pattern gauge-based bottom CD; and
generating the second layout by performing an ADI retarget operation to correspond to the ACI target.

13. The OPC method of claim 12, wherein the performing of the PPC based on ML further comprises, before performing the gauge clustering operation, calculating a feature-based weight based on a correlation between the bottom CD and the feature,
wherein the performing of the gauge clustering operation comprises performing the gauge clustering operation by using features to which the feature-based weight is applied.

14. The OPC method of claim 12, wherein the calculating of the distribution parameters comprises:
removing an outlier of the cluster by using an Otsu-segmentation algorithm; and
obtaining the skew-normal distribution through fitting after the outlier is removed.

15. A method of manufacturing a mask, the method comprising:
obtaining a first layout of after cleaning inspection (ACI) corresponding to patterns on a wafer;
performing progress proximity correction (PPC) based on machine learning (ML) to generate a second layout of after development inspection (ADI);
performing optical proximity correction (OPC) on the second layout to generate a third layout;
transferring the third layout as mask tape-out (MTO) design data;
preparing mask data based on the MTO design data; and
exposing a mask substrate based on the mask data,
wherein the performing of the PPC based on ML comprises obtaining a pattern gauge-based bottom critical dimension (CD) and features, generating a prediction ML model, based on the pattern gauge-based bottom CD and features, and generating an ACI target including a maximum process window with respect to a maximum limit and a minimum limit of the pattern gauge-based bottom CD predicted through the prediction ML model.

16. The method of claim 15, wherein the performing of the PPC based on ML comprises:
obtaining a pattern gauge-based bottom CD of ACI through measurement of patterns on the wafer and obtaining the pattern gauge-based features from the first layout;
performing a gauge clustering operation of grouping and classifying pattern gauges including similar features;
calculating distribution parameters in a skew-normal distribution of the pattern gauge-based bottom CD in each cluster;
generating the prediction ML model through ML between the distribution parameters and an average feature value in each cluster;
predicting a distribution, a maximum limit, and a minimum limit of the pattern gauge-based bottom CD based on a feature by using the prediction ML model;
generating the ACI target including the maximum process window with respect to the maximum limit and the minimum limit of the pattern gauge-based bottom CD; and
generating the second layout by performing an ADI retarget operation to correspond to the ACI target.

17. The method of claim 16, wherein the performing of the PPC based on ML further comprises, before performing the gauge clustering operation, calculating a feature-based weight based on a correlation between the bottom CD and the feature,
wherein the performing of the gauge clustering operation comprises performing the gauge clustering operation by using features to which the feature-based weight is applied.

18. The method of claim 17, wherein the calculating of the feature-based weight uses a random forest (RF) algorithm, and the performing of the gauge clustering operation uses a balanced iterative reducing and clustering using hierarchies (BIRCH) algorithm.

19. The method of claim 16, wherein the calculating of the distribution parameters comprises:
removing an outlier of the cluster by using an Otsu-segmentation algorithm; and
obtaining the skew-normal distribution through fitting after the outlier is removed.

20. The method of claim 16, wherein the distribution parameters comprise a location, a scale, and a shape respectively corresponding to an average, a standard deviation, and skewness in a normal distribution.
